(19) United States
(12) Patent Application Publication
(10) Pub. No.: US 2025/0378222 A1
(43) Pub. Date: Dec. 11, 2025

(54) COMPUTER-IMPLEMENTED METHOD FOR GENERATING A DIGITAL STATIC TEST DESIGN

(71) Applicant: Krones AG, Neutraubling (DE)

(72) Inventors: Benedikt BOETTCHER, Bruckmühl (DE); Ilona KRAUSE, Neutraubling (DE)

(21) Appl. No.: 19/209,712

(22) Filed: May 15, 2025

(30) Foreign Application Priority Data
Jun. 7, 2024 (DE) 102024115905.7

(51) Int. Cl. G06F 30/17

(52) U.S. Cl. CPC G06F 30/17

(57) ABSTRACT

A computer-implemented method for generating a digital static test design (STD) of a container treatment machine. The digital STD can predict a value of an operating parameter of the container treatment machine based on a target value of a characteristic variable of a container to be treated. The method includes obtaining a obtaining a parameter inertia for operating parameters of the container treatment machine; operating the container treatment machine with a fixed operating parameter value of a first operating parameter with a first parameter inertia and varying at least one second operating parameter with a smaller second parameter inertia than the first parameter inertia; determining at least one characteristic variable of a treated container depending on the operating parameter value of the first operating parameter and the operating parameter values of the second operating parameter; and generating the digital STD based on the operating parameter values and the characteristic variable.

### CROSS-REFERENCE TO RELATED APPLICATIONS

This application claims priority to, and the benefit of, German Patent Application No. 102024115905.7, filed June 7, 2024. The contents of that application are incorporated by reference herein in their entirety.

### TECHNICAL FIELD

The present invention relates to a computer-implemented method for generating a digital static test arrangement, STD, a container treatment machine, and a method for treating a container with a container treatment machine.

### BACKGROUND ART

Digital static test designs (STD) for machines are known from the prior art. These designs are also referred to as Design of Experiment (DoE) and are typically used to adjust the operating parameters of a machine based on desired production results, in particular target values in connection with manufactured products, so that the desired production result is achieved as reliably as possible and with as little deviation as possible.

For example, a digital STD can be used to control a blow molding process of a blow molding machine in such a way that a certain degree of transmittance or reflectance of the container produced can be achieved with the operating parameters used.

It is known that such a digital STD must first be generated based on an operation of the corresponding machine, such as in particular a container treatment machine, with varying operating parameters and characteristic variables derived therefrom of the containers produced with these operating parameters.

However, this is time-consuming because the dynamic behavior of the container treatment machine reacts differently to changes in different operating parameters.

### BRIEF SUMMARY

Aspects of the invention relate to generating a digital static test design (STD) of a container treatment machine, such that the digital STD can be generated with a shorter operating time of the container treatment machine,but maintaining consistently high quality.

One particular aspect of the invention relates to a computer- implemented method for generating a digital static test design (STD) of a container treatment machine, wherein the digital STD can predict a value of an operating parameter of the container treatment machine based on a target value of a characteristic variable of a container to be treated. The method comprises:

obtaining a parameter inertia for operating parameters of the container treatment machine;

operating the container treatment machine with a fixed operating parameter value of a first operating parameter with a first parameter inertia and varying at least one second operating parameter with a smaller second parameter inertia than the first parameter inertia;

determining at least one characteristic variable of a treated container depending on the operating parameter value of the first operating parameter and the operating parameter values of the second operating parameter;

generating the digital STD based on the operating parameter values and the characteristic variable.

The computer-implemented method is to be understood as a method that is carried out at least partly within or by a computer, in particular when creating the digital STD. However, one or more steps can also be carried out physically. This applies in particular to the step of operating the container treatment machine with the selected operating parameter values (hereinafter also referred to as parameter values or operating parameters for short). Since the creation of the digital STD requires the creation or treatment of containers in order to determine the actually obtained characteristic values for the selected parameter values of the operating parameters and to generate the digital STD based on these, an actual physical operation of the container treatment machine must usually take place.

In this respect, the computer-implemented method can also be understood as a general method in which at least some steps take place or are carried out within a computer.

While the digital STD is suitable for predicting a value of an operating parameter of the container treatment machine based on a target value of a characteristic variable of a container to be treated, it is understood that the invention also includes the reverse. The digital STD can therefore also be used or is suitable to predict the value of a characteristic variable of a container to be treated based on a given combination of operating parameters.

The term parameter inertia generally refers to the inertia or delay in the response of the container treatment machine to a change in the parameter value of the relevant operating parameter. This can vary depending on the conditions of the container treatment machine and the operating parameters. In particular, the time required for the container treatment machine to return to a stable state when the relevant operating parameter is changed can vary. The time required to reach such a stable state here depends on the operating parameter and the behavior of the container treatment machine when it changes.

If the operating parameter is, for example, a temperature of blow molds of a blow molding machine (as an example of a container treatment machine), it takes longer until the container treatment machine has returned to a stable state (i.e. the blow molds have heated up to or cooled down to the specified temperature) due to the heat that the blow molds have to give off or additionally absorb when the blow mold temperature changes. If the operating parameter is a temperature of a heating element, such as an IR emitter or a microwave emitter of an oven or other heating device of the blow molding machine, adjusting the temperature may also take a longer time, since cooling or heating of the heating elements is usually not possible instantaneously (i.e. without a time delay). If, on the other hand, the operating parameter is the blowing pressure, a stable state of the container treatment machine can be reached very quickly if the blowing pressure changes, since the blowing pressure is in principle changed without any time delay from a first value that was used to treat a first container to a second value for treating a second container. For example, a pre-blowing time can also be adjusted correspondingly quickly from a first value to a second value in place of or in addition to a blowing pressure, substantially without any time delay.

The characteristic variable of a container is basically any variable that defines a physical or chemical characteristic of the container. This includes for example the transparency or the transmittance behavior or the reflectance behavior or, for example, the degree of stretching of the plastics material of a blow-molded container. Other characteristic variables can also be understood here, and the invention is not limited to specific characteristic variables. Since values of the characteristic variables usually depend on the selected operating parameters, by varying the operating parameters and subsequently measuring the characteristic values for the containers treated with the relevant combinations of operating parameters, it is possible to derive how the characteristic values of the manufactured container or containers depend on the choice of operating parameters.

If the change in the operating parameters in the sense of the invention is divided depending on their parameter inertia, the time required to run through all combinations of variations in the operating parameters to create the digital STD can be shortened, since the variation in the operating parameters takes place in an ordered manner depending on their parameter inertia. This allows the digital STD to be created in a shorter time while maintaining the same quality, which can in particular reduce the operating time and thus also the energy outlay required to create the STD.

It can be provided that the first parameter inertia is the largest parameter inertia.

The largest parameter inertia is understood here as the parameter inertia of the corresponding operating parameter that is largest among all parameter inertias of the operating parameters that are to be varied to create the digital STD. This further reduces the time required to generate the digital STD.

In one embodiment, it is provided that the operation comprises operating with fixed parameter values of all operating parameters with a parameter inertia that is greater than the smallest parameter inertia of one of the operating parameters, and varying the operating parameter or parameters with the smallest parameter inertia.

With this embodiment, an iterative process can be carried out, starting with a variation of the operating parameter or parameters having the smallest parameter inertia. Subsequently, a variation of the operating parameters with the next largest parameter inertia can be carried out, and so on, until finally a variation of the operating parameter(s) with the largest parameter inertia takes place.

In particular, a variation of operating parameters with the smallest parameter inertia up to operating parameters with larger parameter inertia can be provided.

This division of the variation of the operating parameters depending on their parameter inertia further reduces the time required to generate the digital STD.

In one embodiment, it is provided that the characteristic variable is at least one of a transmission behavior, an emission behavior, a breaking strength of at least a part of the container.

These characteristic variables can be significantly influenced by the operating parameters used, particularly in connection with manufacturing machines for producing preforms and/or blow molding machines. The digital STD created based on the operating parameters and these characteristic variables can therefore be used advantageously to control or regulate, for example, blow molding processes or preform manufacturing processes.

It can be provided that the container treatment machine is a preform manufacturing machine, a blow molding machine, a heating device or a filler. The heating device or heater can, for example, comprise one or more heating elements, such as infrared emitters (IR emitters) or microwave emitters or laser emitters or any combination thereof, to heat preforms. The heating device can be configured as a straight tunnel or a multi-level tunnel through which the preforms can be transported.

Since the operating parameters of these machines can in part have a very large influence on the characteristic variables of the containers treated, the use of a digital STD together with these machines is particularly advantageous.

The operating parameter with the greatest parameter inertia can be a temperature of a component or of an operating medium of the container treatment machine. In particular, the process parameter with the greatest parameter inertia can be a temperature or radiation power of a heating element of a heating device, such as an IR emitter, a microwave emitter or a laser emitter.

Since the time required to stabilize the operation of the container treatment machine is usually very long when there are temperature changes of components or operating media, this embodiment further reduces the time required to create the digital STD, since a variation of this operating parameter occurs less frequently.

It can be provided that the method comprises training a neural network or an adaptive algorithm based on the operating parameter values and the characteristic variable for generating the digital STD. Other known machine learning algorithms can also be used here.

The term adaptive algorithm refers to a deterministic program or algorithm that can be optimized through learning processes. In contrast to neural networks, however, the output of this algorithm (here, for example, the parameter values of the operating parameters to be used for certain target values of the characteristic variables) is deterministic, so that the output can be predicted if the input is known. Neural networks, on the other hand, are usually considered non-deterministic or a "black box" because, due to their complexity, an exact prediction of the output given knowledge of the input is generally not possible.

Neural networks or adaptive algorithms are particularly advantageously suited to making the most accurate predictions possible for the operation of the container treatment machine with other operating parameters based on a finite number of variations of the operating parameters and the characteristic variables determined for this purpose, so that a digital STD generated with these properties can be used particularly advantageously for the reliable operation of a container treatment machine.

The method can include varying all operating parameters influencing the characteristic variable to generate the digital STD.

The digital STD generated in this way maps the behavior of the container treatment machine when there is variation of the operating parameters, and the associated influence on the characteristic variables of the containers to be treated, as reliably as possible so that subsequent operation of the container treatment machine can be controlled or regulated particularly reliably using this digital STD.

It can be provided that varying an operating parameter comprises changing the operating parameter from a first value to a second value and a subsequent stabilization phase, wherein during the stabilization phase the container treatment machine changes from a stationary state corresponding to the first value to a stationary state corresponding to the second value.

This embodiment comprises in particular determining the digital STD based only on parameter constellations for which a stationary state of the container treatment machine has been reached. In this context, a stationary state of the container treatment machine is to be understood as a state in which physical parameters do not change or no longer change significantly or, if a change in these parameters is provided, this change takes place as intended for operation. This includes, for example, that after varying from a first value to a second value, the temperature of the components of the container treatment machine has stabilized to the second value, or that a medium pressure is constant or corresponds as closely as possible to the provided time course. This embodiment increases the accuracy of the generated digital STD.

The parameter inertia of an operating parameter can be determined based on a duration or a predicted duration of the stabilization phase.

The duration of the stabilization phase can be measured, for example, by carrying out test runs of the container treatment machine while varying the operating parameters. A predicted duration of the stabilization phase can be determined, for example, based on comparative values from other container treatment machines or based on theoretical calculations on the behavior of the container treatment machine when there is variation of the operating parameters. In one embodiment, the parameter inertia can be equal to the duration of the stabilization phase or can be determined as a function of the stabilization phase.

In one embodiment, it is provided that the digital STD comprises at least one lookup table, LUT, in which operating parameter values of at least one operating parameter are each assigned to a value of the characteristic variable.

Lookup tables, LUT, and their entries are available within the computer with particularly low retrieval costs, so that the selection of suitable operating parameters, for example to achieve a certain target value of a characteristic variable of a container to be treated, can be carried out particularly efficiently with this digital STD.

In a further embodiment, it is provided that the digital STD is configured to extrapolate operating parameter values to be used in a container treatment based on a target value of the characteristic variable based on the used operating parameter values of the operating parameters and of the determined characteristic variables.

By extrapolating, using the digital STD, to ranges of the operating parameters and/or characteristic variables not used during the generation of the digital STD, the number of variations of the operating parameters necessary during the generation of the digital STD can be reduced, which further reduces the time required to create the digital STD.

According to embodiments of the invention, a method for treating a container with a container treatment machine is further provided, the method comprising operating the container treatment machine to treat a container based on a target value of a characteristic variable of the container, wherein at least one operating parameter of the container treatment machine is determined with a digital STD generated with a computer-implemented method according to preceding embodiments, and the operation of the container treatment machine is carried out with the operating parameter.

This method enables reliable treatment of containers.

According to embodiments of the invention, a container treatment machine for treating a container is provided, wherein the container treatment machine can treat the container using at least one adjustable operating parameter, wherein the container treatment machine comprises a control unit with a digital STD generated using a computer-implemented method according to one of the preceding embodiments, and wherein the control unit is configured to determine the at least one adjustable operating parameter using the digital STD based on a target value of a characteristic variable of a container to be treated and to control the container treatment machine for treating the container.

With this container treatment machine, containers with desired target values for characteristic variables can be reliably produced.

Other aspects, embodiments, features, and advantages of the invention will be set forth in the following description.

### BRIEF DESCRIPTION OF THE FIGURES

FIG. 1 shows a flow chart of a computer-implemented method according to an embodiment.

FIG. 2 shows another flow chart of an embodiment of a computer- implemented method.

FIG. 3 shows a schematic view of a container treatment machine according to an embodiment.

FIG. 4 shows a tree diagram illustrating the method according to FIG. 2.

### DETAILED DESCRIPTION

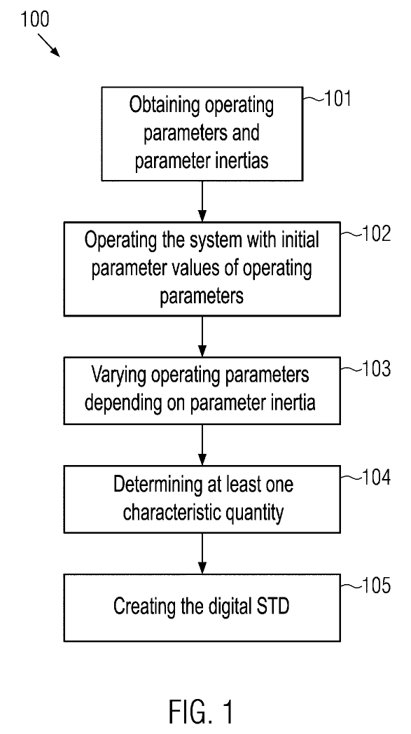

FIG. 1 shows a flow chart of a method 100 for generating a digital static test design, STD, for a container treatment machine. The term container treatment machine is to be understood in the sense of the invention as any machine that can carry out an interaction with a container and/or preform, in which preferably at least one characteristic variable of the container/preform changes.

According to embodiments of the invention, the digital STD is generated in such a way that it can be used in the operation of the container treatment machine to predict a value of an operating parameter of the container treatment machine (i.e. the numerical value of the operating parameter) based on one or more target values of one or more characteristic variables of a container to be treated, and thus, using the digital STD, the container treatment can be carried out with the operating parameters thus predicted, such that after the treatment they have values of the characteristic variable or variables that correspond as closely as possible to the specified target values.

To achieve this, the digital STD is generated by operating the container treatment machine with different values and combinations of values of operating parameters and determining the resulting characteristic variables of the containers to be treated. From this, an assignment of combinations of operating parameters to values of the characteristic variables of the containers treated with these operating parameters can be generated. This allows a prediction of the characteristic variables of the containers for certain combinations of operating parameters during subsequent operation by using the digital STD. It is preferred if the digital STD can not only make predictions for the operating parameters and target values on the basis of which it was generated, but is also able to extrapolate into other ranges of the operating parameters and/or target values, so that reliable predictions of the operating parameters that must be used to achieve certain target values of characteristic variables are possible in as large a parameter space as possible.

The method 100 begins with a first step 101 in which the operating parameters to be considered for generating the digital STD and their associated parameter inertias are obtained. The operating parameters indicate physical and/or chemical variables that are used to operate the container treatment machine. Using the example of a blow molding machine, this can be the blowing pressure or the blowing pressure profile during a blowing process or the movement profile of a stretching rod. Other operating parameters relate, for example, to the temperature of the blowing medium or the temperature of a heating element of a heating device for heating the preforms (such as an IR emitter or a microwave emitter or a laser emitter) of the blow mold or similar.

The above is to be understood by way of example only. The invention is not limited with regard to the operating parameters used and is also not limited with regard to the container treatment machine for which the digital STD is to be generated. In principle, however, it is provided that only those operating parameters which have an influence on the characteristic variables of a container to be achieved during container treatment are preferably used to generate the digital STD. For example, by choosing the operating parameters of the blow molding process, characteristic variables of the container, such as the transmittance or reflectance behavior or the degree of stretching, can be influenced to a certain extent. If the digital STD is to be used to control a blow molding machine to adjust one of these characteristic variables, the digital STD is preferably generated taking into account all operating parameters of the container treatment machine that can influence these characteristic variables. In addition, it can be provided that other operating parameters which have no influence on the characteristic variables are not taken into account for generating the digital STD.

In the sense of the invention, the parameter inertias assigned to the operating parameters are to be understood as a measure of the duration of the response of the container treatment machine to a change in the relevant operating parameter. In this sense, the duration of the response of the container treatment machine is, for example, a duration of a stabilization phase of the container treatment machine after a change in the relevant operating parameter. The stabilization phase can be understood as the phase through which the container treatment machine goes in order to assume a stationary state after a value of an operating parameter has changed from a first value to a second value. This duration of the stabilization phase depends on the relevant operating parameters.

Using the example of the blowing pressure used to form a container in a blow molding machine, it is clear that in principle this pressure can be changed from one container to the following container if the valves and circuits of the blow molding machine are suitably configured, without, for example, there being deviations in the temporal profile of the blowing pressure or in its level. The blow molding machine therefore has a low parameter inertia with regard to the blowing pressure used.

However, if the temperature of the blowing medium, such as compressed air, or the temperature of the blow molds for the blow molding process is changed, this is usually accompanied by a cooling process or a heating process of one or more components of the blow molding machine. This cannot be done instantaneously. An exchange of heat is necessary, so that, for example, a change in the blow mold temperature from a first temperature to a second temperature cannot take place instantaneously, but rather requires for example heating up or cooling down the blow molds, which can take up to several minutes. During this time, the temperature of the components of the blow molding machine changes (essentially following an exponential law), so that during this time blow molding of a container would not take place with the provided value of the operating parameter (here the blow mold temperature), but with a temperature lying between the first temperature and the second temperature. Thus, only when enough time has passed for the blow mold to be heated or cooled to the desired second temperature has the blow molding machine reached the stationary state.

In this sense, the parameter inertia of the container treatment machine with respect to the blow molding temperature is greater than the parameter inertia of the blow molding machine with respect to a change in the blowing pressure. It is understood that the parameter inertia depends not only on the type of operating parameter (temperature, pressure, etc.), but also on the magnitude of the change in the operating parameter. This can obviously be the case in particular with the temperature of media or components.

The operating parameters to be used to generate the digital STD and their inertias can, for example, be stored in a storage medium or obtained by test runs of the container treatment machine in step 101. For example, one or more containers can be treated with a small number of varied operating parameters in order to determine whether characteristic variables of the containers treated in this way depend on the corresponding operating parameters, and it can be determined simultaneously or additionally how long the container treatment machine needs to return to a stationary state after changing a parameter value of one of the operating parameters. From this, the parameter inertias can then be determined, for example as numerical values, and assigned to the corresponding operating parameters.

In the subsequent step 202, the container treatment machine is now operated with first parameter values of operating parameters. For example, a first temperature of the blow mold and a first blowing pressure can be used. The containers treated (in this case manufactured) with these operating parameters can then be examined with regard to their characteristic variables in order to determine which values of the characteristic variables result from this combination of operating parameters. This can preferably be done in fully automated fashion, for example by inspecting the containers treated in the container treatment machine with the help of one or more suitable inspection devices in order to determine values for the relevant characteristic variables.

In step 103, one of the operating parameters is then varied depending on the parameter inertia, i.e. the corresponding parameter value is changed. According to the invention, in step 103 at least one operating parameter with a higher parameter inertia is not varied (i.e. is held constant) and at least one operating parameter with a lower parameter inertia than this higher parameter inertia is varied. Again, the values of the characteristic variables of the containers are determined for the now varied combination of parameter values (104). According to the invention, step 103 is carried out repeatedly while holding the operating parameter with the associated greater parameter inertia until all provided variations of the operating parameter with the lower parameter inertia have been run through.

The characteristic variables thus determined (step 104 and after step 102) of the treated containers are then assigned according to the combinations of varied operating parameters. This can then be used to generate a digital STD in a known manner by feeding a prediction model provided for the STD with the obtained combinations.

The digital STD can, for example, also be configured as a neural network or adaptive algorithm, so that parameters of the neural network or the adaptive algorithm can be adjusted in a fundamentally known manner by running through the corresponding variations of the operating parameters. For example, a prediction of the neural network or adaptive algorithm for a characteristic variable of a treated container based on the selected combination of operating parameters can be compared with the actually resulting value of the characteristic variable for this combination of operating parameters and, based on this, training of the neural network or adaptive algorithm can take place in the usual way until the prediction accuracy of the neural network or the adaptive algorithm reaches a desired accuracy, for example within specified limits.

Subsequently, a set of combinations of operating parameters not used during training can be used to check the predictive accuracy of the neural network or the adaptive algorithm, or more generally the digital STD, by comparing the predicted values for the one or more characteristic variables with the determined values of the characteristic variables. If, here as well, the accuracy of the prediction is within a, for example, previously defined tolerance, then the learning of the neural network or adaptive algorithm when generating the digital STD can be considered to be completed and the digital STD can be generated with the trained neural network or adaptive algorithm in step 105.

Since the determination of the characteristic variables for combinations of operating parameters is carried out in such a way that, when the values of an operating parameter with a larger parameter inertia are fixed, a variation of at least one operating parameter with a smaller parameter inertia takes place, time is saved for the run-throughs of the container treatment machine. At the same time, the energy required during operation of the container treatment machine is reduced.

Nevertheless, the container treatment machine runs through all provided variations of operating parameters so that the generated digital STD has consistent accuracy.

This creates an option for generating a digital STD that requires less time to generate the digital STD while maintaining the same prediction accuracy of the operating parameters for particular target values of characteristic variables.

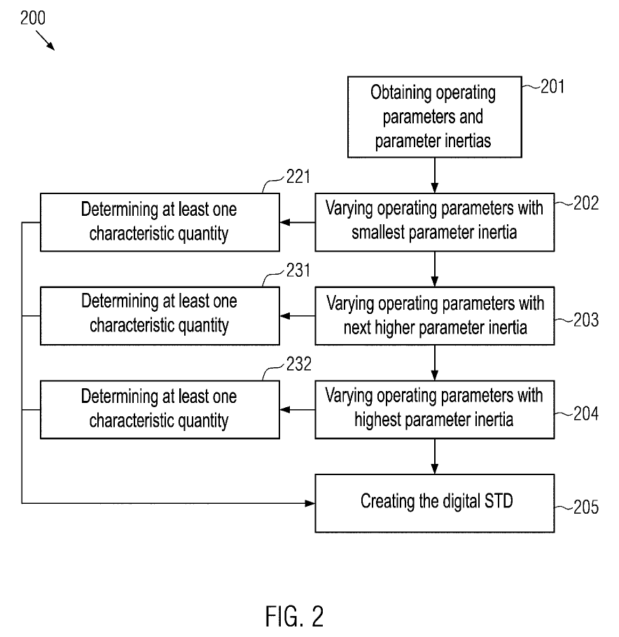

FIG. 2 shows another embodiment of a method 200 for generating a digital STD. In principle, all embodiments described with reference to FIG. 1 are also applicable in conjunction with the embodiment of FIG. 2. In particular, the digital STD generated in the embodiment of FIG. 2 can also be obtained by training a neural network or adaptive algorithm, or this can be part of generating the digital STD.

While in the embodiment of FIG. 1 a reduction in the operating times of the container treatment machine required for generating the digital STD was already achieved by holding an operating parameter with a higher parameter inertia and (complete) variation of an operating parameter with a lower parameter inertia, in the embodiment of FIG. 2 a complete ordering and variation of the operating parameters takes place depending on the associated parameter inertias, so that the operating duration of the container treatment machine and thus the time for generating the digital STD is reduced even further.

Analogous to FIG. 1, in the first step 201 of the method, the operating parameters to be varied and the associated parameter inertias are first obtained.

Subsequently, the variation of the operating parameters is carried out in such a way that the variation of the operating parameters takes place in ascending order according to their parameter inertia, so that the variation of the operating parameter or parameters with the smallest parameter inertia begins in step 202.

In this step 202, all operating parameters with a higher parameter inertia are held constant, i.e. left at a fixed value, and only the operating parameter(s) with the smallest parameter inertia are varied. The measured characteristic variables associated with the corresponding operating parameters are determined in step 221, as already described in connection with FIG. 1.

In the next step 203, the operating parameter(s) are then varied with the next higher parameter inertia, while the operating parameters with an even higher parameter inertia are held constant. In step 203, the operating parameters with a smaller parameter inertia can also be held constant or these can be varied together with the operating parameters with the next higher parameter inertia in order to be able to map any multidimensional influences of the variations of various operating parameters on the characteristic variable or characteristic variables of the container to be treated.

Again, in step 231, during the variation of the operating parameters in step 203 the corresponding characteristic variables of the treated containers are determined.

This method is carried out successively with a variation of operating parameters with increasing parameter inertia until a variation of the operating parameters with the highest parameter inertia takes place in step 204. Here too, it can be provided that when the operating parameter with the highest parameter inertia is varied or changed from a first value to a second value, all operating parameters with a lower parameter inertia are varied while the operating parameter with the highest parameter inertia is held constant, in order to also correctly map the influence of the characteristic variables by changing the operating parameters.

Analogous to steps 221 and 231, the characteristic variable or variables of the containers treated are also determined in this part of the method.

On the basis of the combinations thus determined of operating parameters and characteristic variables of the containers treated with these operating parameters, the digital STD is then generated in step 205, as has already been described in connection with FIG. 1.

While it can be provided that the operating parameters are ordered according to their parameter inertia in such a way that only those operating parameters with the same parameter inertia are varied in one step of the method, it can also be provided that operating parameters with the same or only approximately the same parameter inertia are varied. For example, it can be provided that operating parameters are grouped according to their parameter inertia, wherein a group can, for example, comprise all operating parameters with a parameter inertia that deviates by less than, for example, 10% of the mean value of the parameter inertia of the group. Other criteria for combining operating parameters into groups based on their parameter inertia are also possible.

The method according to the embodiment of FIG. 2 is then carried out in such a way that a variation of operating parameters of a group is carried out, whereas the operating parameters of the remaining groups with higher parameter inertia are held constant.

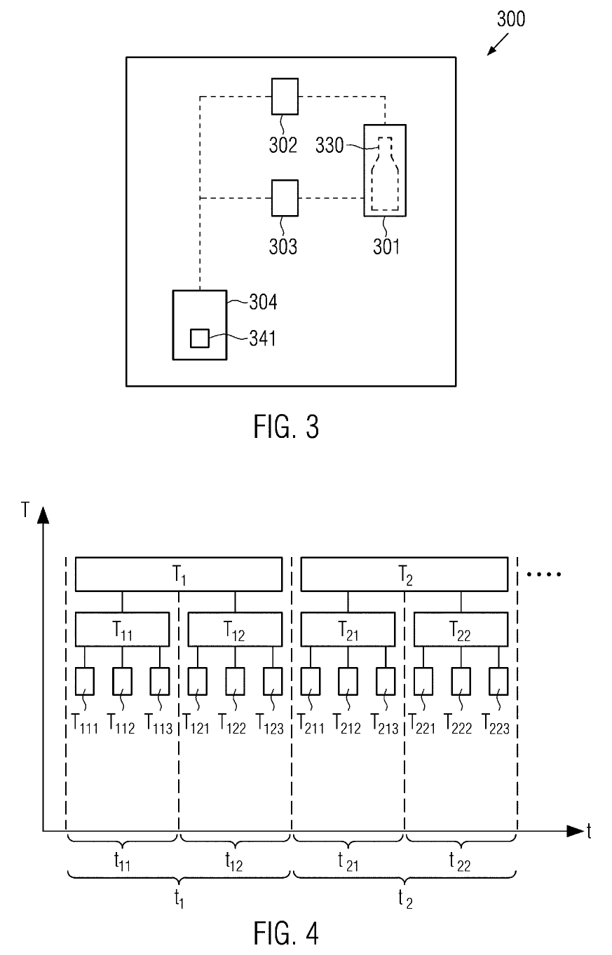

FIG. 3 schematically shows an embodiment of a container treatment machine 300 using the example of a blow molding machine. The embodiment is schematic and serves for better understanding.

The blow molding machine 300 comprises at least one, preferably a plurality of blow molds 301. These are connected to further components 302 and 303 (number here only as an example) for the operation of the blow molding machine. The components 302 and 303 can be, for example, heating devices for the blow mold 301 and/or a stretching rod and/or a media supply for a blowing medium. The blow molding process is characterized by operating parameters and their parameter values and can, for example, include a specific temperature of the blow mold 301 and thus, for example, of the associated heating element 302 as well as a movement profile of the stretch rod 303.

These parameters influence the result of the blow molding process by, for example, influencing the transmittance or reflectance of the blow-molded container or the degree of stretching of the PET material of the blow-molded container.

The blow molding machine 300 further comprises a control unit 304 which can be configured, for example, as a computer with associated memory and is preferably configured to control the components 301, 302 and 303 of the blow molding machine 300 so that they can be operated with specified parameter values for the corresponding operating parameters in order to produce a container 330 with the blow molding machine 300 from a preform. These methods are basically known. Different components or parts of the blow molding machine, such as heating elements or individual blow molds, can also be operated with different operating parameters while the digital SVB is being created and the operating parameters of the components can be varied. For example, the individual behavior of a blow mold and its associated components or a radiant heater can be specifically taken into account when creating the STD.

According to one embodiment, the control unit 304 includes a digital STD 341 generated according to one of the preceding methods. During operation of the blow molding machine 300, the control unit 304 can be given certain values for one or more characteristic variables of the containers to be molded, for example by an operator. For example, a degree of transmittance of the container to be formed can be specified. The control unit can then, by using the digital STD, determine the operating parameters to be used for the components of the blow molding machine based on the target value(s) for the characteristic variable or variables of the containers and control the blow molding machine depending on the target values to be achieved for the containers to be produced.

This reduces the need for operator intervention to set the operating parameters of the blow molding machine and at the same time improves the accuracy with which the operating parameters of the blow molding machine can be set to obtain containers with values of the characteristic variables as close as possible to the target values.

To further explain the method according to FIG. 2, FIG. 4 shows a tree diagram illustrating the variation of the operating parameters according to their parameter inertia. In the tree diagram, two additional axes are shown: an inertia axis T for a parameter inertia, and a time axis t.

The method begins at any point in time by setting a parameter value for an operating parameter with the largest parameter inertia T1. According to FIGURE2, a value is now set for an operating parameter with a lower parameter inertia, here initially T12. Then a parameter value T111 is set for an operating parameter with even lower parameter inertia. In this embodiment, the tree diagram comprises three different parameter inertia levels, from the highest parameter inertia (one digit as index) to the lowest parameter inertia (three digits as index).

While the parameter value Ti is now held constant for a time period t1, the parameter value of the operating parameter with the lowest parameter inertia is first varied from the value T111 through T112 up to T113 for a period t11 in which the parameter value T12 is also held constant. While three variation steps are shown here, it is understood that more or fewer are also possible.

The parameter value is then changed from T11 to T12. Over a period of time t12 this value is held constant and the parameter values of an operating parameter with lower parameter inertia are varied (here the values T121, T122, T123).

This procedure is carried out iteratively until all variations of the operating parameter with the second-highest parameter inertia have been run through (here the operating parameter with two digits as index). Subsequently, and thus after time t1, the parameter value of the operating parameter with the largest parameter inertia is changed from T1 to T2. Over the time period t2, during which T1 is held constant, operating parameters with lower parameter inertia are now varied. This is done analogously to the time period t1. The parameter value of the operating parameter with the next-lowest parameter inertia is initially set to the value T21. Over the period t21, the operating parameters with even lower parameter inertia are varied (values T211, T212, T213). Then the value of the operating parameter with the next-lowest parameter inertia is set to the value T22 and over the time period t22 the operating parameters with even lower parameter inertia (values T221, T222, T223) are varied.

For each of the variations of parameter values described in connection with FIG. 4, the characteristic variables are then determined according to FIG. 2 and are used to generate the digital STD.

This allows the digital STD to be generated in a time-saving manner, since variations for operating parameters with higher parameter inertia are changed as infrequently as possible. At the same time, the STD is created with high accuracy, since all necessary variations can still be run through.

What is claimed is:

1. A computer-implemented method for generating a digital static test design (STD) of a container treatment machine, wherein the digital STD can predict a value of an operating parameter of the container treatment machine based on a target value of a characteristic variable of a container to be treated, the method comprising:
obtaining a parameter inertia for operating parameters of the container treatment machine;
operating the container treatment machine with a fixed operating parameter value of a first operating parameter with a first parameter inertia and varying at least one second operating parameter with a smaller second parameter inertia than the first parameter inertia;
determining at least one characteristic variable of a treated container depending on the operating parameter value of the first operating parameter and the operating parameter values of the second operating parameter;
generating the digital STD based on the operating parameter values and the characteristic variable.

2. The computer-implemented method according to claim 1, wherein the first parameter inertia is the largest parameter inertia.

3. The computer-implemented method according to claim 1, wherein the operation comprises operating with fixed parameter values of all operating parameters with a parameter inertia that is greater than the smallest parameter inertia of one of the operating parameters, and varying the operating parameter or parameters with the smallest parameter inertia.

4. The computer-implemented method according to claim 3, wherein varying is done of operating parameters with the smallest parameter inertia up to operating parameters with larger parameter inertia.

5. The computer-implemented method according to claim 1, wherein the characteristic variable is at least one of a transmission behavior, an emission behavior, a fracture strength of at least a part of the container.

6. The computer-implemented method according to claim 1, wherein the container treatment machine is a preform manufacturing machine, a blow molding machine, or a filler.

7. The computer-implemented method according to claim 1, wherein the operating parameter with the greatest parameter inertia is a temperature of a component or an operating medium of the container treatment machine.

8. The computer-implemented method according to claim 1, wherein the method comprises training a neural network or an adaptive algorithm based
on the operating parameter values and the characteristic variable to generate the digital STD.

9. The computer-implemented method according to claim 1, wherein the method comprises varying all operating parameters that influence the characteristic variable to generate the digital STD.

10. The computer-implemented method according to claim 1, wherein varying an operating parameter comprises changing the operating parameter from a first value to a second value and a subsequent stabilization phase, wherein during the stabilization phase the container treatment machine changes from a stationary state corresponding to the first value to a stationary state corresponding to the second value.

11. The computer-implemented method according to claim 10, wherein the parameter inertia of an operating parameter is determined based on a duration or a predicted duration of the stabilization phase.

12. The computer-implemented method according to claim 1, wherein the digital STD comprises at least one lookup table, LUT, in which operating parameter values of at least one operating parameter are each assigned to a value of the characteristic variable.

13. The computer-implemented method according to claim 1, wherein the digital STD is configured to extrapolate operating parameter values to be used in a container treatment based on a target value of the characteristic variable based on the used operating parameter values of the operating parameters and of the determined characteristic variables.

14. A method for treating a container with a container treatment machine, the method comprising operating the container treatment machine to treat a container based on a target value of a characteristic variable of the container, wherein at least one operating parameter of the container treatment machine is determined with a digital STD generated with a computer-implemented method according to claim 1, and the operation of the container treatment machine is carried out with the operating parameter.

15. A container treatment machine for treating a container, wherein the container treatment machine treats the container using at least one adjustable operating parameter, wherein the container treatment machine comprises a control unit with a digital STD generated using a computer-implemented method according to claim 1, and wherein the control unit is configured to determine the at least one adjustable operating parameter using the digital STD based on a target value of a characteristic variable of a container to be treated and to control the container treatment machine for treating the container.
